(19) United States
(12) Patent Application Publication
(10) Pub. No.: US 2026/0086450 A1
(43) Pub. Date: Mar. 26, 2026

(54) SRAF CONTROL METHOD AND SYSTEM FOR WAFER EXPOSURE, AND MASK MANUFACTURING METHOD USING THE METHOD

(71) Applicant: Samsung Electronics Co., Ltd., Suwon-si (KR)

(72) Inventors: Yong Su Jung, Suwon-si (KR); Moo-Joon Shin, Suwon-si (KR); Kyung Jae Park, Suwon-si (KR)

(21) Appl. No.: 19/032,417

(22) Filed: Jan. 20, 2025

(30) Foreign Application Priority Data
Sep. 25, 2024 (KR) 10-2024-0129777

(51) Int. Cl. G03F 1/72; G03F 7/00

(52) U.S. Cl. CPC G03F 1/72; G03F 7/0005; G03F 7/70441; G03F 7/70508; G03F 7/70525

(57) ABSTRACT

The SRAF control method may include obtaining an SRAF corresponding to a mask and a plurality of control points that were preset for the SRAF, generating a plurality of fake polygons for adjusting the SRAF on a virtual grid on a substrate where the mask and the SRAF are positioned, defining weights between centers of the plurality of fake polygons and the plurality of control points to become greater as distances between the centers of the plurality of fake polygons and the plurality of control points decrease, and adjusting the SRAF based on the weights that were defined and size variations of the plurality of fake polygons to reduce edge placement error (EPE) between the mask and a layout pattern corresponding to preset defocus and dedose conditions for the mask while preventing printing of the SRAF on a wafer.

### CROSS-REFERENCE TO RELATED APPLICATION

This application claims priority from Korean Patent Application No. 10-2024-0129777 filed on Sep. 25, 2024 in the Korean Intellectual Property Office, and all the benefits accruing therefrom under 35 U.S.C. 119, the contents of which in its entirety are herein incorporated by reference.

### BACKGROUND

The present disclosure relates to a sub-resolution assist feature (SRAF) control method and system using fake polygons, and a mask manufacturing method using the SRAF control method, and more specifically, to a method for enhancing the process window in an exposure process by controlling an SRAF through fake polygon control.

In semiconductor processing, photolithography using a mask may be conducted to form patterns on a semiconductor substrate, such as a wafer. Briefly, a mask is a pattern transfer medium in which opaque material patterns are formed on a transparent base. The process of manufacturing the mask starts with the design of a required circuit, followed by layout design for the circuit. The resulting mask design data, obtained via optical proximity correction (OPC), is then transmitted as mask tape-out (MTO) design data. Based on the MTO design data, mask data preparation (MDP) is performed, followed by front-end-of-line (FEOL) processes, such as exposure, and back-end-of-line (BEOL) processes, such as defect inspection, to complete the fabrication of the mask.

Specifically, OPC is the process of reducing edge placement error (EPE), which is the discrepancy between layout patterns and simulated contours, while changing the shape of the mask. Particularly in the case of a complex curvilinear mask generated through inverse lithography technology (ILT), tens of mask points may exist per layout pattern, making it challenging to fine-tune EPE. When each of these mask points is individually controlled, there is a risk of the mask being adjusted in a way that lacks smoothness. To address this, a method has been proposed to indirectly control the tens of mask points.

### SUMMARY

Aspects of the present disclosure provide a method for controlling a sub-resolution assist feature (SRAF) by varying the size of fake polygons to reduce edge placement error (EPE) under defocus and dedose conditions, without printing the SRAF on a wafer.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a sub-resolution assist feature (SRAF) control method performed by a computing device. The SRAF control method may include obtaining an SRAF corresponding to a mask and a plurality of control points that were preset for the SRAF, generating a plurality of fake polygons for adjusting the SRAF on a virtual grid on a substrate where the mask and the SRAF are positioned, defining weights between centers of the plurality of fake polygons and the plurality of control points to become greater as distances between the centers of the plurality of fake polygons and the plurality of control points decrease, adjusting the SRAF based on the weights that were defined and size variations of the plurality of fake polygons to reduce edge placement error (EPE) between a layout pattern corresponding to preset defocus and dedose conditions for the mask and the mask while preventing the SRAF from being printed on a wafer, generating design data for the mask as a corrected layout image based on the SRAF that was adjusted, and transmitting a control signal to perform exposure on the wafer based on the mask.

According to the aforementioned and other embodiments of the present disclosure, there is provided a sub-resolution assist feature (SRAF) control system. The SRAF control system may include a processor, and a memory storing instructions, wherein when executed by the processor, the instructions enable the processor to perform operations including obtaining an SRAF corresponding to a mask and a plurality of control points that were preset for the SRAF, generating a plurality of fake polygons for adjusting the SRAF on a virtual grid on a substrate where the mask and the SRAF are positioned, defining weights between centers of the plurality of fake polygons and the plurality of control points to become greater as distances between the centers of the plurality of fake polygons and the plurality of control points decrease, and adjusting the SRAF based on the weights that were defined and size variations of the plurality of fake polygons to reduce edge placement error (EPE) between a layout pattern corresponding to preset defocus and dedose conditions for the mask and the mask while preventing the SRAF from being printed on a wafer, generating design data for the mask as a corrected layout image based on the SRAF that was adjusted, and transmitting a control signal to perform exposure on the wafer based on the mask.

According to the aforementioned and still other embodiments of the present disclosure, there is provided a mask manufacturing method performed by a computing device. The mask manufacturing method may include obtaining a sub-resolution assist feature (SRAF) corresponding to a mask and a plurality of control points that were preset for the SRAF, generating a plurality of fake polygons for adjusting the SRAF on a virtual grid on a substrate where the mask and the SRAF are positioned, defining weights between centers of the plurality of fake polygons and the plurality of control points to become greater as distances between the centers of the plurality of fake polygons and the plurality of control points decrease, and adjusting the SRAF based on the weights that were defined and size variations of the plurality of fake polygons to reduce edge placement error (EPE) between a layout pattern corresponding to preset defocus and dedose conditions for the mask and the mask while ensuring that the SRAF is not printed on a wafer, obtaining design data for the mask, transmitting the design data as mask tape-out (MTO) design data, preparing mask data based on the MTO design data, and transmitting a control signal to perform exposure on the wafer based on the mask data.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a block diagram illustrating an example computing device for performing optical proximity correction (OPC) according to some embodiments of the present disclosure;

FIG. 2 is a flowchart illustrating a sub-resolution assist feature (SRAF) control method according to some embodiments of the present disclosure;

FIG. 3 illustrates an SRAF, fake polygons, layout pattern, and mask according to some embodiments of the present disclosure;

FIG. 4 is a flowchart illustrating an example of step S400 of FIG. 2, which is the step of adjusting an SRAF;

FIG. 5 illustrates an example of calculating edge placement error (EPE) between a layout pattern corresponding to defocus and dedose conditions and a mask, according to some embodiments of the present disclosure;

FIG. 6 is a flowchart illustrating another example of step S400 of FIG. 2, which is the step of adjusting an SRAF;

FIG. 7 illustrates an example SRAF update process based on a resist image (RI) signal according to some embodiments of the present disclosure;

FIG. 8 is a flowchart illustrating an SRAF control method according to some embodiments of the present disclosure; and

FIG. 9 is a flowchart illustrating a semiconductor manufacturing method according to some embodiments of the present disclosure.

### DETAILED DESCRIPTION

Hereinafter, preferred embodiments of the present disclosure will be described in detail with reference to the attached drawings. Advantages and features of the present disclosure, and a method of achieving the advantages and features will become apparent with reference to embodiments described later in detail together with the accompanying drawings. However, embodiments of the present disclosure are not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure gist of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise.

Additionally, in describing the components of the present disclosure, terms such as first, second, A, B, a, and b may be used. These terms are only used to distinguish one component from another component, and the nature, sequence, order, or number of the component are not limited by the term. It should be understood that when a component is described as being “connected,” “coupled,” or “combined” to another component, the component may be directly connected, coupled, or combined to another component, still another component may be “interposed” therebetween, and thus the component may be connected, coupled, or combined to another component via the sill another component.

It will be further understood that the terms “comprise”, “comprising”, “include”, and “including” as used herein specify the presence of the stated features, steps, operations, elements, and/or components, but do not preclude the presence or addition of one or more other features, steps, operations, elements, components, and/or portions thereof.

A sub-resolution assist feature (SRAF) is generally derived separately from the mask through ILT. Although the SRAF can be modified through the fine-tuning of the aforementioned mask, in most cases, the modified SRAF does not achieve optimal conditions from the perspective of focus and dose. Accordingly, to improve the process window, a method for fine-tuning the SRAF to minimize or reduce EPE under optimal defocus and dedose conditions is contemplated. Dedose refers to a dose that is outside an allowable range from the best dose.

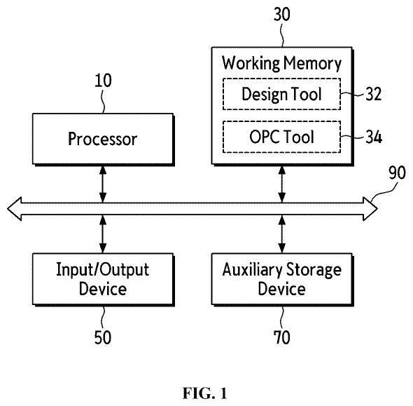

FIG. 1 is a block diagram illustrating an example computing device for performing optical proximity correction (OPC) according to some embodiments of the present disclosure. Referring to FIG. 1, the computing device may include a processor 10, a working memory 30, an input/output device 50, and an auxiliary storage device 70. The computing device in FIG. 1 may be provided as a dedicated device for generating and calibrating an OPC model and may be equipped with various design and verification simulation programs.

The processor 10 may execute software (e.g., applications, an operating system (OS), device drivers) to be run on the computing device. The processor 10 may execute an OS (not illustrated) loaded in the working memory 30. The processor 10 may execute various application programs driven on an OS-based platform. For example, the processor 10 may run a design tool 32, such as a layout design tool, and/or an OPC tool 34 loaded in the working memory 30. The processor 10 may include at least one type of processor well-known in the technical field of the present disclosure, such as a central processing unit (CPU), a microprocessor unit (MPU), a microcontroller unit (MCU), or a graphics processing unit (GPU).

The OS or application programs may be loaded in the working memory 30. During the boot of the computing device, an OS image (not illustrated) stored in the auxiliary storage device 70 may be loaded into the working memory 30 based on a boot sequence. Various input/output operations of the computing device may be supported by the OS. Application programs may be loaded into the working memory 30 in response to user selection or for the provision of basic services. The design tool 32 and/or the OPC tool 34 may be loaded from the auxiliary storage device 70 to the working memory 30.

The design tool 32 may be equipped with a bias function that enables the design tool 32 to modify the shapes and positions of specific layout patterns differently from those defined by design rules. Additionally, the design tool 32 may perform a design rule check (DRC) under modified bias data conditions. The OPC tool 34 may perform optical proximity correction (OPC) on layout data output from the design tool 32.

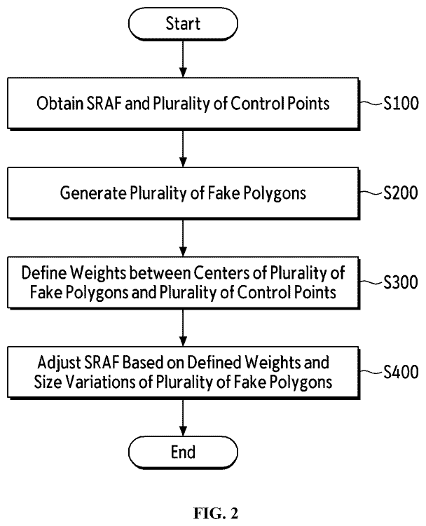

The OPC tool 34 may control a sub-resolution assist feature (SRAF) to improve the process window of an exposure process by minimizing or reducing edge placement error (EPE) between a layout pattern corresponding to preset defocus and dedose conditions and a mask. Specifically, the OPC tool 34 may generate virtual fake polygons on a substrate where the mask and SRAF are formed, and may finely adjust the size of the SRAF by adjusting the size of the fake polygons. To prevent the SRAF from becoming excessively large and consequently printed on a wafer in an actual exposure process, the OPC tool 34 may optimize the layout of the SRAF. Examples related to this will be described later with reference to FIGS. 2 through 8.

For example, the working memory 30 may be a volatile memory such as a dynamic random-access memory (DRAM) or static random-access memory (SRAM) or may be a non-volatile memory such as a flash memory, phase change random-access memory (PRAM), resistance random-access memory (RRAM), nano floating gate memory (NFGM), polymer random-access memory (PoRAM), magnetic random-access memory (MRAM), or ferroelectric random-access memory (FRAM).

The input/output device 50 controls user input and output from user interface devices. For example, the input/output device 50 may be equipped with a keyboard and/or monitor to receive information from a designer. The input/output device 50 may be used to receive information on semiconductor regions or data paths that may need adjusted operating characteristics. The processing steps and results from the OPC tool 34 may also be displayed via the input/output device 50.

The auxiliary storage device 70 is provided as a storage medium for the computing device. The auxiliary storage device 70 may store application programs, the OS image, and various data. The auxiliary storage device 70 may be provided as a memory card (e.g., an MMC, eMMC, SD, MicroSD) or a hard disk drive (HDD). The auxiliary storage device 70 may include a NAND-type flash memory with high storage capacity. In some embodiments, the auxiliary storage device 70 may include a next-generation non-volatile memory such as a PRAM, MRAM, ReRAM, or FRAM, or a NOR flash memory.

A system interconnector 90 may be a system bus for providing a network within the computing device. Through the system interconnector 90, the processor 10, the working memory 30, the input/output device 50, and the auxiliary storage device 70 may be electrically connected and exchange data with one another. However, the configuration of the system interconnector 90 is not particularly limited and may further include arbitration means for efficient management.

FIG. 2 is a flowchart illustrating an SRAF control method according to some embodiments of the present disclosure. For reference, FIGS. 2, 4, 6, 8, and 9 illustrate steps/operations of an SRAF control method or a mask manufacturing method performed by the computing device in FIG. 1. Accordingly, in the following description, when a specific step/operation lacks an explicitly stated subject, it can be understood as being performed by the computing device in FIG. 1.

In step S100, an SRAF corresponding to a first mask and a plurality of preset control points for the SRAF may be obtained. In step S100, the first mask may represent a contour image of an actual mask extracted from layout images of an optical proximity-corrected mask and may be a curvilinear mask generated using inverse lithography technology (ILT). The SRAF, introduced to address OPC deviation issues caused by pattern density differences, affects surrounding patterns, and is formed at a size that is smaller than the resolution of exposure equipment so that it is not printed onto a resist layer as a pattern.

The control points refer to a set of points forming the SRAF, and may be connected to one another using curves or straight lines to form the SRAF. Additionally, when the positions of the control points are changed, the layout of the SRAF can be finely adjusted. In other words, fine-tuning the layout of the SRAF can be achieved by changing the positions of the control points. Like the first mask, the SRAF may also be a curvilinear pattern generated using ILT. Meanwhile, there may be more than one SRAF corresponding to the first mask. Although the following embodiments will be described assuming that there exists a single SRAF, they may also be applied to the presence of more than one SRAF. The expression “fine-tuning the layout of the SRAF” may be simply referred to as “adjusting the SRAF.”

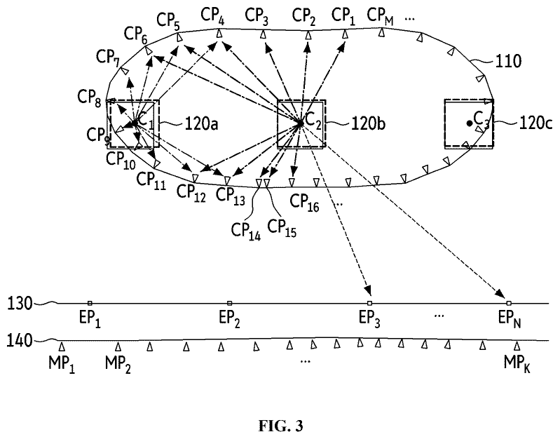

In step S200, a plurality of fake polygons for adjusting the SRAF may be generated on a virtual grid formed on a substrate on which the first mask and the SRAF are located. The virtual grid formed on the substrate is a grid formed on the same plane as the substrate where the first mask and the SRAF are located, and may be composed of two perpendicular axes. The fake polygons for adjusting the SRAF may be generated around each point of the grid. The fake polygons are virtual shapes intended solely for adjusting the SRAF, and may take any shape. However, for case of explanation, the fake polygons in FIG. 3 are assumed to be rectangular.

In step S300, weights may be defined between the centers of the fake polygons and the control points. The weights may be defined to be greater when the distances between the centers of the fake polygons and the control points are smaller, and the weights may be defined to be smaller when the distances between the centers of the fake polygons and the control points are greater. Furthermore, no weights may be defined between the control points and the centers of fake polygons more than a predetermined distance apart from the SRAF. The definitions of the SRAF, the fake polygons, the first mask, and the weights will hereinafter be described in detail with reference to FIG. 3 below.

FIG. 3 illustrates an SRAF, fake polygons, layout pattern, and mask according to some embodiments of the present disclosure. Referring to FIG. 3, an SRAF 110 may include a plurality of control points CP₁ through CP_{M}. The control points CP₁ through CP_{M} are connected to form the SRAF 110, and are illustrated in FIG. 3 as being connected by a curve. Thus, the example SRAF 110 in FIG. 3 may correspond to a curvilinear SRAF.

Meanwhile, weights may be defined between the control points CP₁ through CP_{M} and centers C₁, C₂, and C₃ of fake polygons 120a, 120b, and 120c. For example, in FIG. 3, control points and fake polygon centers with defined weights are connected by arrows, and the shorter the arrows (i.e., the closer the distances between the control points and the fake polygon centers), the greater the weight that may be set. For example, the weights may be defined as the exponential distances between the control points CP₁ through CP_{M} and the centers C₁, C₂, and C₃ of the fake polygons 120a, 120b, and 120c. Specifically, if the distance between a control point CPᵢ and a fake polygon center point Cⱼ is denoted as distᵢⱼ, the exponential distance may be defined as exp (−distᵢⱼ/λ), where λ may be an arbitrary constant.

A position change CV_{CP,j} of a control point CPⱼ according to the size variation of an i-th fake polygon may be expressed by Equation 1 below.

$${CV}_{CP , j} = \frac{{\sum }_{i \sim fakepoly} ( {w}_{ij} * {CV}_{fake , i} )}{{\sum }_{i \sim fakepoly} {w}_{ij}} \qquad [ Equation 1 ]$$

Referring to Equation 1, wᵢⱼ denotes the weight defined between a fake polygon center point Cᵢ and the control point CPⱼ, and CV_{fake,i} represents the size variation (e.g., area change) of the i-th fake polygon for which a weight is defined with the control point CPⱼ.

The fake polygons 120a, 120b, and 120c may be generated on the same plane as the SRAF 110 and the mask 140, as previously described. For example, the centers C₁, C₂, and C₃ of the fake polygons 120a, 120b, and 120c may correspond to points on a virtual grid formed on the substrate where the SRAF 110 and the mask 140 are positioned. Although only one SRAF 110 and three fake polygons 120a, 120b, and 120c are illustrated in FIG. 3, this is a non-limiting example and there may exist greater numbers of SRAFs and/or fake polygons.

A layout pattern 130 may correspond to a layout pattern corresponding to preset defocus and dedose conditions for the exposure process of the mask 140, i.e., a pattern intended to be generated on a wafer under the preset defocus and dedose conditions. A plurality of evaluation points EP₁ through EP_{N} are positioned on the layout pattern 130. The evaluation points EP₁ through EP_{N} may serve as reference points when calculating EPE with the mask 140.

The mask 140 may correspond to the first mask described with reference to FIG. 2 and may be derived from the layout image of an actual optical proximity-corrected mask. FIG. 3 illustrates only a partial mask 140, and a plurality of mask points MP₁ through MP_{K} are depicted on the mask 140. EPE may be calculated between each of the evaluation points EP₁ through EP_{N} on layout pattern 130 and each of the mask points MP₁ through MP_{K} on the mask 140. This calculated EPE, which is related to the preset defocus and dedose conditions, may be referred to as process window EPE.

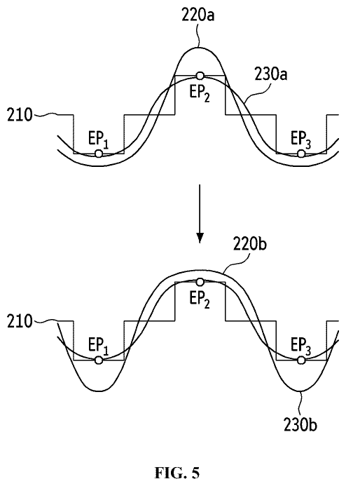

Meanwhile, when the SRAF 110 is adjusted by changing the size of the fake polygons 120a, 120b, and 120c, the contour of the layout pattern 130 (the curve connecting the evaluation points EP₁ through EP_{N}) may also be changed accordingly, and any change in the contour of the layout pattern 130 may result in a contour change in the mask 140. Therefore, a specific relationship may also be present between each of the centers C₁, C₂, and C₃ of the fake polygons 120a, 120b, and 120c and each of the evaluation points EP₁ through EP_{N} on the layout pattern 130. Changes in the contours of the layout pattern 130 and the mask 140 will be explained later in further detail with reference to FIG. 5.

Returning to FIG. 2, in step S400, the SRAF may be adjusted based on the defined weights and the size variations of the fake polygons. Here, the adjustment of the SRAF may be performed under two conditions. The first condition is that the EPE (or the process window EPE mentioned above with reference to FIG. 3) between the first mask and the layout pattern corresponding to the preset defocus and dedose conditions for the first mask is minimized or reduced. The second condition is that the SRAF is not printed on an actual wafer. In other words, the size of the SRAF may be increased in the process of minimizing or reducing the process window EPE, but not to the extent that it becomes large enough to be printed on the wafer.

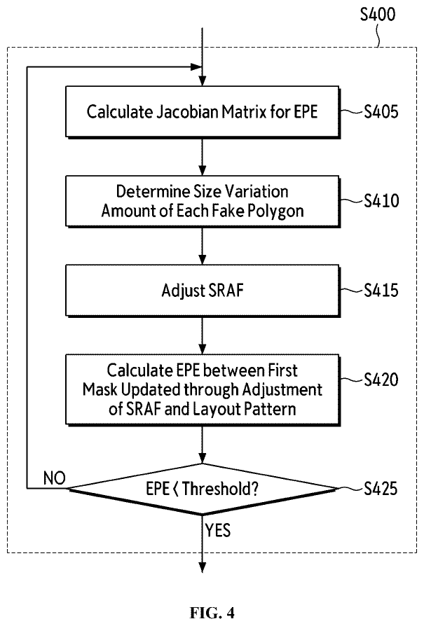

Embodiments where the SRAF is adjusted according to the aforementioned two conditions will hereinafter be described with reference to FIGS. 4 through 7.

FIG. 4 is a flowchart illustrating an example of step S400 of FIG. 2, which is the step of adjusting the SRAF. Referring to FIG. 4, in step S405, a Jacobian matrix, which includes the differentials of the size variations of the fake polygons with respect to the EPE (or the process window EPE) calculated between the first mask and the layout pattern corresponding to the defocus and dedose conditions for the first mask, may be calculated. Here, the Jacobian matrix may be expressed as the differential (de/dCV_{fake}) of an EPE at an arbitrary position with respect to a size variation CV_{fake} of a fake polygon. Here, CV_{fake} may correspond to CV_{fake,i}, the size variation of the i-th fake polygon, as described above with reference to Equation 1.

In step S410, based on the calculated Jacobian matrix, the size variation amounts of the fake polygons may be determined. For example, step S410 may be performed using a gradient descent method. Thereafter, in step S415, the SRAF may be adjusted based on the determined size variation amount. Specifically, the position variation amount of each of the control points of the SRAF may be calculated, as shown in Equation 1, based on the determined size variation amount, and the layout of the SRAF may be finely adjusted according to the calculated position variation amount. Thereafter, in step S420, the EPE between the layout pattern and the first mask updated through the fine adjustment of the SRAF may be recalculated.

Here, the update of the first mask means that the contour of the first mask is changed (or updated) according to the contour of the layout pattern obtained from the adjustment of the SRAF adjustment. In step S425, it may be determined whether the EPE between the updated first mask and the layout pattern is below a predetermined threshold. If the EPE is below the predetermined threshold (“YES”), further adjustment of the SRAF may be performed depending on whether the SRAF is printed on a wafer. If the EPE is not below the predetermined threshold (“NO”), step S405 and its subsequent steps may be repeated.

If the EPE is below the predetermined threshold, the depth-of-focus (DOF) when printing the first mask on a wafer may be calculated. The calculation of the EPE between the layout pattern and the first mask will hereinafter be explained with reference to FIG. 5.

FIG. 5 illustrates an example of calculating the EPE between a layout pattern corresponding to defocus and dedose conditions and a mask, according to some embodiments of the present disclosure. Referring to FIG. 5, a layout pattern 210 represents a layout pattern corresponding to predetermined defocus and dedose conditions, and may correspond to the layout pattern 130 in FIG. 3. Three evaluation points EP₁, EP₂, and EP₃ are illustrated as being on the layout pattern 210. A contour 220a corresponds to the contour of a mask (e.g., the mask 140 in FIG. 3 or the first mask in FIG. 2), and a contour 230a corresponds to the contour of the layout pattern 210. The EPE (or process window EPE) between the layout pattern 210 and the mask may be calculated based on the contours 220a and 230a.

Thereafter, when the Jacobian matrix is calculated and the SRAF is adjusted as described above with reference to FIG. 4, the layout pattern 210 and the evaluation points EP₁, EP₂, and EP₃ remain the same, but the pattern change in the SRAF may result in changes in the contours 220b and 230b. The EPE calculated in this state between the layout pattern 210 and the mask may correspond to the EPE between the layout pattern and the updated first mask, as described above with reference to FIG. 4.

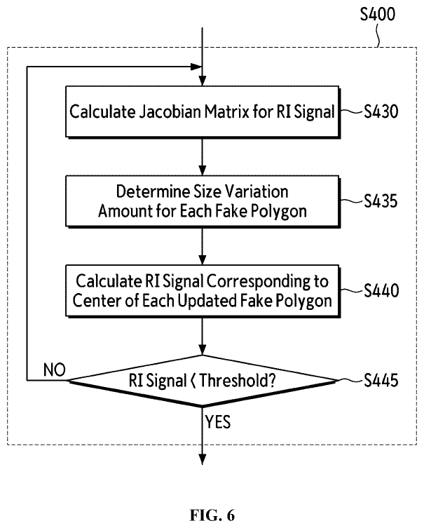

FIG. 6 is a flowchart illustrating another example of step S400 of FIG. 2, which is the step of adjusting an SRAF. Referring to FIG. 6, in step S430, a Jacobian matrix, which includes the differential of the size variation of each of the fake polygons with respect to a resist image (RI) signal calculated at its center, may be calculated. Here, the Jacobian matrix may be expressed as the differential (dRI/dCV_{fake}) of the RI signal with respect to the size variation CV_{fake}.

In step S435, based on the calculated Jacobian matrix, the size variation amount for each of the fake polygons may be determined. For example, step S435 may be performed using a gradient descent method. Thereafter, in step S440, an RI signal corresponding to the center of each updated (or size-adjusted) fake polygon may be recalculated based on the determined size variation amount. In step S445, it may be determined whether the recalculated RI signal is below a predetermined threshold. Specifically, an SRAF including even a single fake polygon with an RI signal that exceeds the predetermined threshold may be printed on a wafer, and an SRAF including all the fake polygons whose RI signals are below the predetermined threshold may not be printed on a wafer.

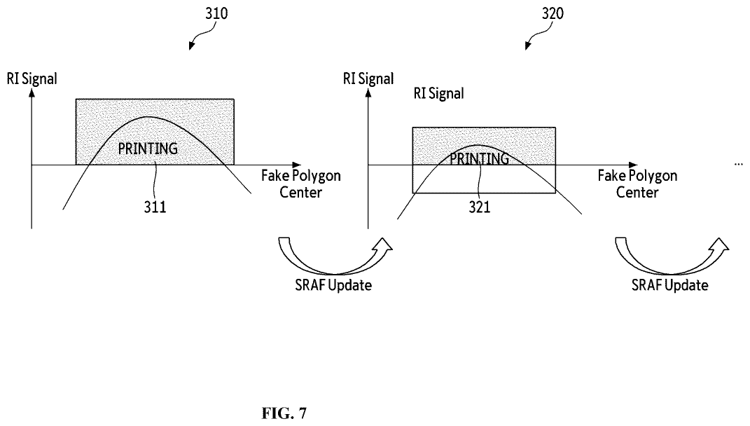

If the recalculated RI signal is below the predetermined threshold (“YES”), the SRAF may not be printed on a wafer, and the adjustment of the SRAF may be terminated. If the recalculated RI signal is not below the predetermined threshold (“NO”), step S430 and its subsequent steps may be repeated. For example, if the recalculated RI signal is not below the predetermined threshold (“NO”), fake polygons with a recalculated RI signal exceeding the predetermined threshold may be selectively chosen, and the selected fake polygons may be subject again to step S430 and its subsequent steps. An SRAF update process based on an RI signal will hereinafter be described with reference to FIG. 7.

FIG. 7 illustrates an example SRAF update process based on an RI signal according to some embodiments of the present disclosure. FIG. 7 depicts graphs 310 and 320. Both the graphs 310 and 320 show the magnitude of an RI signal for each fake polygon center, with a predetermined threshold of 0. In other words, an SRAF containing a fake polygon with a positive RI signal may be printed on a wafer, and an SRAF containing a fake polygon with a zero or negative RI signal may not be printed on a wafer.

Thus, an SRAF including fake polygons corresponding to regions 311 and 321 where RI signals are greater than zero may be printed on a wafer through an exposure process. Therefore, by repeatedly updating the size of only the fake polygons in the regions 311 and 321 until there are no fake polygons with an RI signal greater than zero, the SRAF can be prevented from being printed on a wafer.

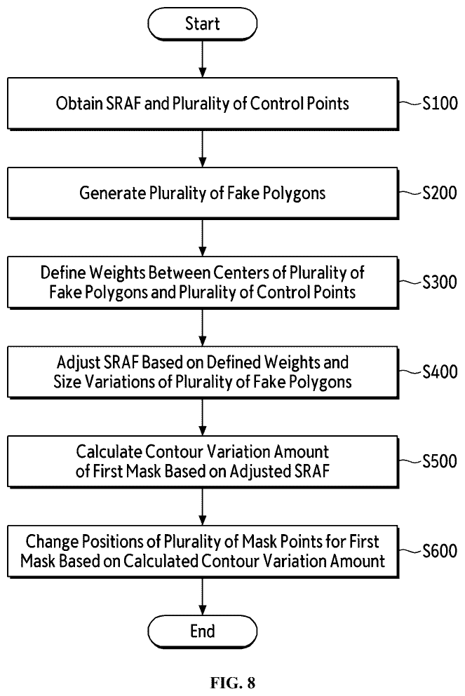

FIG. 8 is a flowchart illustrating an SRAF control method according to some embodiments of the present disclosure. Referring to FIG. 8, after step S400, which is the step of adjusting the SRAF, in step S500, the contour variation amount of the first mask may be calculated based on the results of step S400. Thereafter, in step S600, the positions of a plurality of preset mask points on the first mask may be changed to correspond to the calculated contour variation amount.

For example, in some embodiments, the positions of the mask points on the first mask may be changed by directly adjusting the mask points. In some embodiments, an arbitrary fake mask corresponding to the first mask may be introduced, weights may be set between the mask points of the fake mask and the mask points of the first mask, and the mask points of the first mask may be indirectly adjusted by adjusting the mask points of the fake mask. In either example, the positions of the mask points on the first mask may be changed to correspond to the contour variation amount of the first mask determined by the contour change of the layout pattern.

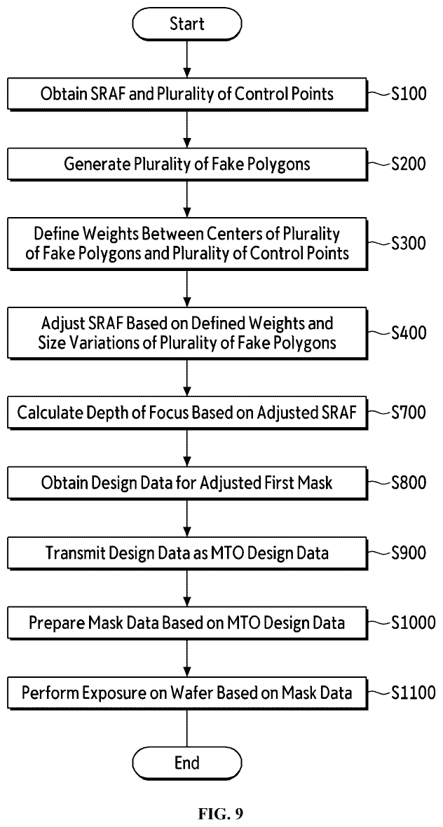

FIG. 9 is a flowchart illustrating a semiconductor manufacturing method according to some embodiments of the present disclosure. Referring to FIG. 9, a mask manufacturing method (hereinafter referred to simply as the “mask manufacturing method”) including an SRAF control method according to some embodiments of the present disclosure may involve sequentially performing steps ranging from step S100, where an SRAF corresponding to a first mask and a plurality of preset control points for the SRAF are obtained, to step S400, where the SRAF is adjusted based on defined weights and the size variations of a plurality of fake polygons. Additionally, in some embodiments, the mask manufacturing method may further include steps S500 and S600 described above with reference to FIG. 8. Since steps S100, S200, S300, and S400 are as described earlier with reference to FIG. 2, and steps S500 through S600 are as described earlier with reference to FIG. 8, overlapping descriptions will be omitted.

In step S700, based on the results of the adjustment of the SRAF, the DOF when printing the first mask on a wafer may be calculated. In step S800, design data for the adjusted first mask may be obtained. That is, the adjusted first mask may be finalized as an optical proximity-corrected layout image. In step S900, the obtained design data may be transmitted as MTO design data. Generally, MTO may refer to sending final mask data obtained through an OPC process to a mask fabrication team to request mask production. Therefore, the MTO design data may be substantially the same as final optical proximity-corrected layout image data obtained through a mask layout correction method. This MTO design data may use a graphic data format used in electronic design automation (EDA) software. For example, the MTO design data may be in a format such as Graphic Data System II (GDS2) or Open Artwork System Interchange Standard (OASIS).

Thereafter, in step S1000, preparing of the mask data, such as MDP, may be performed based on the MTO design data. MDP may include, for example, format conversion, referred to as, for example, fracturing, augmentation of barcodes for machine reading, standard mask patterns for inspection, job decks, etc., and verification in both automatic and manual modes. Job decks may refer to text files that contain a set of instructions, such as layout information of multiple mask files, reference doses, exposure speeds and methods, etc.

Meanwhile, format conversion, i.e., fracturing, may refer to a process of dividing MTO design data by region and converting it to a format suitable for an electron beam exposure device. Fracturing may involve data manipulation processes such as scaling, data sizing, rotation, pattern mirroring, and color inversion. During a fracturing-based conversion process, data may be corrected to account for various systematic errors that may occur during the transfer from design data to a wafer image. This data correction process for systematic errors is referred to as mask process correction (MPC) and may include tasks such as line width control, known as critical dimension (CD) adjustment, and precision enhancement of pattern placement. Therefore, fracturing may contribute to improving the quality of a final mask and may be a process that can be performed in advance for MPC. Here, systematic errors may be caused by distortions occurring in an exposure process, a mask development and etching process, and a wafer imaging process.

In addition, MDP may include MPC. As previously described, MPC refers to the process of correcting errors, i.e., systematic errors, that occur during an exposure process. Here, the exposure process may broadly include electron beam writing, development, etching, and baking. Furthermore, data processing may be performed prior to the exposure process. Data processing, which is a type of preprocessing for mask data, may include syntax checks for the mask data, exposure time estimation, etc. Through this MDP, E-beam data for wafer exposure may be generated.

In step S1100, after the MDP, an exposure process may be performed on the wafer using the mask data, i.e., the E-beam data. Here, the exposure process may refer to, for example, an E-beam writing process. The E-beam writing process may be performed using, for example, a gray writing method with a multi-beam mask writer (MBMW). Additionally, the E-beam writing process may also be performed using a variable shape beam (VSB) writer. Furthermore, the E-beam writing process may be based on the DOF calculated in step S700. That is, the exposure process may be performed on the wafer based on the DOF and the mask data.

Meanwhile, after the MDP, the process of converting the E-beam data into pixel data may be performed prior to the exposure process. The pixel data is data directly used in actual exposure and may include data on exposure target shapes and the assigned E-beam dose for each exposure target shape. Here, the exposure target shape data may be bitmap data into which vector shape data has been converted through rasterization.

After the exposure process, a series of processes may be performed to complete the mask. These processes may include, for example, development, etching, and cleaning. Additionally, the series of processes for mask manufacturing may include metrology, defect inspection, and defect repair. A pellicle application process may also be included. A pellicle may be a thin, transparent membrane that covers a photomask during the production. Here, the pellicle application process refers to attaching a pellicle to the surface of the mask to protect the mask from contamination during transportation and throughout its usable lifetime, after confirming that there are no contamination particles or chemical stains through final cleaning and inspection.

Meanwhile, the SRAF control method according to some embodiments of the present disclosure may be executed by the computing device of FIG. 1. For example, the OPC tool 34 in FIG. 1 may non-transitorily store one or more computer programs, which, when loaded into the working memory 30, include one or more instructions that cause the processor 10 to perform operations/methods according to various embodiments of the present disclosure. That is, the processor 10 may perform the operations/methods according to the various embodiments of the present disclosure by executing the loaded instructions.

For example, a computer program non-transitorily stored in the OPC tool 34 may enable the operations of obtaining an SRAF corresponding to a first mask and a plurality of preset control points for the SRAF, generating a plurality of fake polygons for adjusting the SRAF on a virtual grid formed on a substrate where the first mask and the SRAF are positioned, defining weights between the centers of the fake polygons and the control points to become greater as the distances between the fake polygon centers and the control points decrease, and adjusting the SRAF based on the defined weights and the size variations of the fake polygons to minimize or reduce the EPE between the first mask and a layout pattern corresponding to preset defocus and dedose conditions for the first mask while ensuring that the SRAF is not printed on a wafer.

According to the embodiments of the present disclosure, an SRAF can be adjusted indirectly through fake polygons, instead of directly adjusting the SRAF, thereby reducing the computational complexity because the number of fake polygons can be fewer than the number of control points needed for directly adjusting the SRAF. Moreover, according to the embodiments of the present disclosure, since both the condition for minimizing or reducing EPE to meet defocus and dedose conditions and the condition for preventing the SRAF from being printed on a wafer are considered, the challenges associated with simultaneously addressing both conditions when directly adjusting the SRAF size can be reduced. Furthermore, according to the embodiments of the present disclosure, fine adjustments of both mask patterns and the SRAF layout can be performed simultaneously.

Various embodiments of the present disclosure and the effects according to those embodiments have been mentioned above with reference to FIG. 1 to FIG. 9. The effects according to the technical idea of the present disclosure are not limited to the effects as mentioned above, and other effects not mentioned may be clearly understood by those skilled in the art from the above descriptions.

All the components that constitute the embodiments of the present disclosure are described as being combined with each other or operating in combination with each other. However, the present disclosure is not necessarily limited to this embodiment. In other words, within the scope of the purpose of the present disclosure, all of the components may operate in a selective combination manner of at least two thereof with each other.

Although the operations are shown as being executed in a specific order in the drawings, it should not be understood that the operations should be performed in the specific order as shown or in a sequential order or that all illustrated operations should be performed to obtain the desired result.

Although embodiments of the present disclosure have been described with reference to the accompanying drawings, embodiments of the present disclosure are not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A sub-resolution assist feature (SRAF) control method performed by a computing device, the SRAF control method comprising:
obtaining an SRAF corresponding to a mask and a plurality of control points that were preset for the SRAF;
generating a plurality of fake polygons for adjusting the SRAF on a virtual grid on a substrate where the mask and the SRAF are positioned;
defining weights between centers of the plurality of fake polygons and the plurality of control points, wherein the weights are respectively greater as distances between the centers of the plurality of fake polygons and the plurality of control points decrease;
adjusting the SRAF based on the weights that were defined and size variations of the plurality of fake polygons to reduce edge placement error (EPE) between the mask and a layout pattern corresponding to preset defocus and dedose conditions for the mask, while preventing printing of the SRAF on a wafer;
generating design data for the mask as a corrected layout image based on the SRAF that was adjusted; and
transmitting a control signal to perform exposure on the wafer based on the mask.

2. The SRAF control method of claim 1, wherein the defining the weights comprises defining the weights as exponential distances between the centers of the plurality of fake polygons and the plurality of control points.

3. The SRAF control method of claim 1, wherein the adjusting the SRAF comprises:
calculating a Jacobian matrix, which includes a differential of respective ones of the size variations of each of the plurality of fake polygons with respect to the EPE between the layout pattern and the mask;
determining a size variation amount of each of the plurality of fake polygons based on the Jacobian matrix;
adjusting the SRAF based on the size variation amount that was determined;
determining an updated EPE between the mask that was updated by the adjusting the SRAF and the layout pattern; and
determining whether the updated EPE between the mask that was updated and the layout pattern is below a predetermined threshold.

4. The SRAF control method of claim 3, wherein the determining whether the updated EPE between the mask that was updated and the layout pattern is below the predetermined threshold comprises:
calculating a depth of focus (DOF) for printing the mask on the wafer if the updated EPE between the mask that was updated and the layout pattern is below the predetermined threshold.

5. The SRAF control method of claim 1, wherein the adjusting the SRAF comprises:
calculating a Jacobian matrix, which includes a differential of respective ones of the size variations of each of the plurality of fake polygons with respect to corresponding resist image (RI) signals determined at corresponding ones of the centers of corresponding ones of the plurality of fake polygons;
determining a size variation amount of each of the plurality of fake polygons based on the Jacobian matrix;
updating the RI signals corresponding to the respective centers of each of the plurality of fake polygons updated based on the size variation amount that was determined; and
determining whether the RI signals corresponding to the respective centers of each of the plurality of fake polygons that were updated is below a predetermined threshold.

6. The SRAF control method of claim 5, wherein the Jacobian matrix is a first Jacobian matrix, and
wherein the determining whether the RI signals are below the predetermined threshold comprises:
determining a first fake polygon among the plurality of fake polygons that were updated with a corresponding one of the RI signals exceeding the predetermined threshold;
calculating a second Jacobian matrix, which includes a differential of a respective one of the size variations of the first fake polygon with respect to the corresponding one of the RI signals determined at the center of the first fake polygon;
determining a size variation amount of the first fake polygon based on the second Jacobian matrix;
updating the corresponding one of the RI signals corresponding to a center of the first fake polygon that was updated based on the determined size variation amount; and
determining whether the corresponding one of the RI signals corresponding to the center of the first fake polygon that was updated is below the predetermined threshold.

7. The SRAF control method of claim 1, further comprising:
determining a contour variation amount of the mask based on results of the adjusting the SRAF; and
changing positions of a plurality of preset mask points for the mask to correspond to the contour variation amount that was determined.

8. The SRAF control method of claim 1, wherein the mask and the SRAF are curvilinear and generated using inverse lithography technology (ILT).

9. A sub-resolution assist feature (SRAF) control system comprising:
a processor; and
a memory storing instructions,
wherein when executed by the processor, the instructions cause the processor to perform operations comprising:
obtaining an SRAF corresponding to a mask and a plurality of control points that were preset for the SRAF;
generating a plurality of fake polygons for adjusting the SRAF on a virtual grid on a substrate where the mask and the SRAF are positioned;
defining weights between centers of the plurality of fake polygons and the plurality of control points, wherein the weights are respectively greater as distances between the centers of the plurality of fake polygons and the plurality of control points decrease;
adjusting the SRAF based on the weights that were defined and size variations of the plurality of fake polygons to reduce edge placement error (EPE) between the mask and a layout pattern corresponding to preset defocus and dedose conditions for the mask, while preventing printing of the SRAF on a wafer;
generating design data for the mask as a corrected layout image based on the SRAF that was adjusted; and
transmitting a control signal to perform exposure on the wafer based on the mask.

10. The SRAF control system of claim 9, wherein the defining the weights comprises defining the weights as exponential distances between the centers of each of the plurality of fake polygons and the plurality of control points.

11. The SRAF control system of claim 9, wherein the adjusting the SRAF comprises:
calculating a Jacobian matrix, which includes a differential of respective ones of the size variations of each of the plurality of fake polygons with respect to the EPE between the layout pattern and the mask;
determining a size variation amount of each of the plurality of fake polygons based on the Jacobian matrix;
adjusting the SRAF based on the size variation amount that was determined;
determining an updated EPE between the mask that was updated by the adjusting the SRAF and the layout pattern; and
determining whether the updated EPE between the mask that was updated and the layout pattern is below a predetermined threshold.

12. The SRAF control system of claim 11, wherein the determining whether the updated EPE between the mask that was updated and the layout pattern is below the predetermined threshold comprises:
calculating a depth of focus (DOF) for printing the mask on a wafer if the updated EPE between the mask that was updated and the layout pattern is below the predetermined threshold.

13. The SRAF control system of claim 9, wherein the adjusting the SRAF comprises:
calculating a Jacobian matrix, which includes a differential of respective ones of the size variations of each of the plurality of fake polygons with respect to corresponding resist image (RI) signals determined at corresponding ones of the centers of corresponding ones of the plurality of fake polygons;
determining a size variation amount of each of the plurality of fake polygons based on the Jacobian matrix;
updating the RI signals corresponding to the respective centers of each of the plurality of fake polygons updated based on the size variation amount that was determined; and
determining whether the RI signals corresponding to the respective centers of each of the plurality of fake polygons that were updated is below a predetermined threshold.

14. The SRAF control system of claim 13, wherein the Jacobian matrix is a first Jacobian matrix, and
wherein the determining whether the RI signals are below the predetermined threshold comprises:
determining a first fake polygon among the plurality of fake polygons that were updated with a corresponding one of the RI signals exceeding the predetermined threshold;
calculating a second Jacobian matrix, which includes a differential of the respective ones of the size variations of the first fake polygon with respect to the a corresponding one of the RI signals determined at the center of the first fake polygon;
determining a size variation amount of the first fake polygon based on the second Jacobian matrix;
updating the corresponding one of the RI signals corresponding to a center of the first fake polygon that was updated based on the determined size variation amount; and
determining whether the a corresponding one of the RI signals corresponding to the center of the first fake polygon that was updated is below the predetermined threshold.

15. The SRAF control system of claim 9, wherein when executed by the processor, the instructions cause the processor to further perform:
determining a contour variation amount of the mask based on results of the adjusting the SRAF; and
changing positions of a plurality of preset mask points for the mask to correspond to the contour variation amount that was determined.

16. A mask manufacturing method performed by a computing device, the mask manufacturing method comprising:
obtaining a sub-resolution assist feature (SRAF) corresponding to a mask and a plurality of control points that are preset for the SRAF;
generating a plurality of fake polygons for adjusting the SRAF on a virtual grid on a substrate where the mask and the SRAF are positioned;
defining weights between centers of the plurality of fake polygons and the plurality of control points, wherein the weights are respectively greater as distances between the centers of the plurality of fake polygons and the plurality of control points decrease; and
adjusting the SRAF based on the weights that were defined and size variations of the plurality of fake polygons to reduce edge placement error (EPE) between a layout pattern corresponding to preset defocus and dedose conditions for the mask and the mask, while preventing printing the SRAF on a wafer;
obtaining design data for the mask;
transmitting the design data as mask tape-out (MTO) design data;
preparing mask data based on the MTO design data; and
transmitting a control signal to perform exposure on the wafer based on the mask data.

17. The mask manufacturing method of claim 16, wherein the adjusting the SRAF comprises:
calculating a Jacobian matrix, which includes a differential of respective ones of the size variations of each of the plurality of fake polygons with respect to the EPE between the layout pattern and the mask;
determining a size variation amount of each of the plurality of fake polygons based on the Jacobian matrix;
adjusting the SRAF based on the size variation amount that was determined;
determining an updated EPE between the mask that was updated by the adjusting the SRAF and the layout pattern; and
determining whether the updated EPE between the mask that was updated and the layout pattern is below a predetermined threshold.

18. The mask manufacturing method of claim 16, wherein the adjusting the SRAF comprises:
calculating a Jacobian matrix, which includes a differential of respective ones of the size variations of each of the plurality of fake polygons with respect to corresponding resist image (RI) signals determined at corresponding ones of the centers of corresponding ones of the plurality of fake polygons;
determining a size variation amount of each of the plurality of fake polygons based on the Jacobian matrix;
updating the RI signals corresponding to the respective centers of each of the plurality of fake polygons updated based on the size variation amount that was determined; and
determining whether the RI signals corresponding to the respective centers of each of the plurality of fake polygons that were updated is below a predetermined threshold.

19. The mask manufacturing method of claim 16, further comprising:
determining a depth of focus (DOF) for printing the mask on a wafer based on results of the adjusting the SRAF,
wherein the performing the exposure on the wafer comprises transmitting the control signal to perform the exposure on the wafer based on the DOF and the mask data.

20. The mask manufacturing method of claim 16, further comprising:
determining a contour variation amount of the mask based on results of the adjusting the SRAF; and
changing positions of a plurality of preset mask points for the mask to correspond to the contour variation amount that was determined.
